(19) United States
(12) Patent Application Publication
(10) Pub. No.: US 2008/0003821 A1
(43) Pub. Date: Jan. 3, 2008

(54) Method for fabricating semiconductor device

(75) Inventors: Ki-Won Nam, Kyoungki-do (KR); Hyun Ahn, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/716,331

(22) Filed: Mar. 9, 2007

(30) Foreign Application Priority Data
Jun. 29, 2006 (KR) 2006-0059312

(51) Int. Cl. H01L 21/441

(52) U.S. Cl. 438/672; 257/E21.649

(57) ABSTRACT

An insulation layer over a substrate is etched to form a contact hole. A conductive layer is formed over the resultant structure. The conductive layer is etched right before the patterned insulation layer is exposed. The conductive layer is etched again such that the patterned insulation layer is exposed to thereby form a contact plug filling the contact hole.

### CROSS-REFERENCE TO RELATED APPLICATIONS

The present invention claims priority of Korean patent application number 10-2006-0059312, filed on Jun. 29, 2006, which is incorporated by reference in its entirety.

### BACKGROUND OF THE INVENTION

The present invention relates to a method for fabricating a semiconductor device; and more particularly, to a method for fabricating a semiconductor device capable of performing planarization to a substrate having a contact plug.

As well known, a method for forming a plug which is a contact pad in advance at a portion requiring a deep contact has been widely used. However, a serious height difference of a substrate may be generated due to the contact plug and thus, various limitations may be incurred during a subsequent process.

FIG. 1A illustrates a typical contact plug of a semiconductor device, and FIG. 1B illustrates transmission electron microscopy (TEM) of the typical contact plug shown in FIG. 1A. FIGS. 1A and 1B illustrate one of the steps of forming a typical storage node contact of a dynamic random access memory (DRAM).

As shown in FIG. 1A, a patterned inter-layer insulation layer 12 is formed over a substrate 11 where various elements are already formed. In more detail, although not illustrated, an inter-layer insulation layer is etched to form a storage node contact hole. A conductive material is formed to a thickness enough to fill the storage node contact hole and then, subjected to an etch-back process to form a storage node contact plug 13 inside the contact hole. An etch barrier layer 14 is formed over the patterned inter-layer insulation layer 12 and the storage node contact plug 13. A patterned sacrificial layer 15 defining a storage node pattern is formed over the etch barrier layer 14. Although not illustrated, a sacrificial layer formed over the etch barrier layer and the etch barrier layer 14 are etched to form a storage node hole 16. FIG. 1A does not illustrate the etch of the etch barrier layer 14 for easier description of subsequent processes. Although not illustrated, a storage node is formed in the storage node hole 16.

An over etch process is performed such that the conductive material does not remain over the patterned inter-layer insulation layer 12 during the etch-back process of the conductive material.

A global height difference D in which a height of the contact plug 13 is less than that of the patterned inter-layer insulation layer 12 may be incurred due to the etch-back process and the over etch process. The etch barrier layer 14 may not be formed to a uniform thickness due to the global height difference D. Accordingly, a process margin may be reduced during etching the sacrificial layer and the etch barrier layer 14 to form the storage node hole 16. Particularly, at the step of exposing the contact plug 13 while etching the etch barrier layer 14, if the over etch process is performed to the etch barrier layer 14, a punch-through phenomenon P (see FIG. 1B) in which the patterned inter-layer insulation layer 12 is exposed through a portion T1 where the etch barrier layer 14 has a thickness less than desired. Also, a not-open phenomenon N (see FIG. 1B) may be incurred at a portion T2 where the etch barrier layer 14 is formed to a thickness greater than desired.

### SUMMARY OF THE INVENTION

Embodiments of the present invention are directed to provide a method for fabricating a semiconductor device, wherein the method can improve a global height difference after performing an etch-back process to form a contact plug such that a subsequent process margin can be secured.

In accordance with an aspect of the present invention, there is provided a method for fabricating a semiconductor device. The method includes etching an insulation layer over a substrate to form a contact hole in a patterned insulation layer; forming a conductive layer over the resultant structure obtained after forming the contact hole, etching the conductive layer right before the patterned insulation layer is exposed, and etching the conductive layer such that the patterned insulation layer is exposed to thereby form a contact plug filling the contact hole.

In accordance with another aspect of the present invention, there is provided a method for fabricating a semiconductor device. The method includes etching an insulation layer over a substrate to form a contact hole in a patterned insulation layer, forming a polysilicon layer over the resultant structure obtained after forming the contact hole, etching the polysilicon layer right before the patterned insulation layer is exposed, and etching the polysilicon layer such that the patterned insulation layer is exposed to thereby form a contact plug filling the contact hole.

### BRIEF DESCRIPTION OF THE DRAWINGS

FIG. 1A illustrates a typical storage node contact plug of a semiconductor device;

FIG. 1B illustrates transmission electron microscopy (TEM) of the typical storage node contact plug shown in FIG. 1A;

FIGS. 2A to 2G illustrate a method for fabricating a semiconductor device in accordance with an embodiment of the present invention;

FIGS. 3A and 3B illustrate TEM respectively obtained after performing a main etching process and an over etch process to form a storage node contact plug in accordance with another embodiment of the present invention; and

FIGS. 4A and 4B illustrate TEM comparing a typical storage node contact plug to a storage node contact plug in accordance with another embodiment of the present invention.

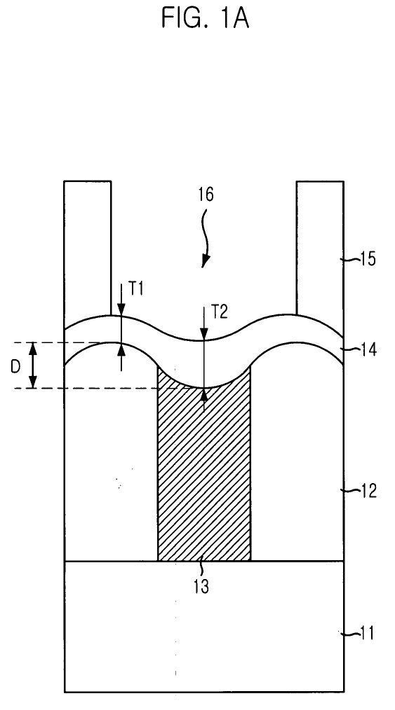

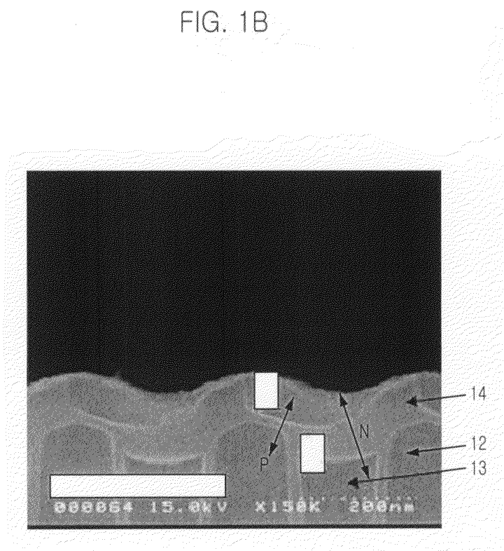

### DESCRIPTION OF SPECIFIC EMBODIMENTS

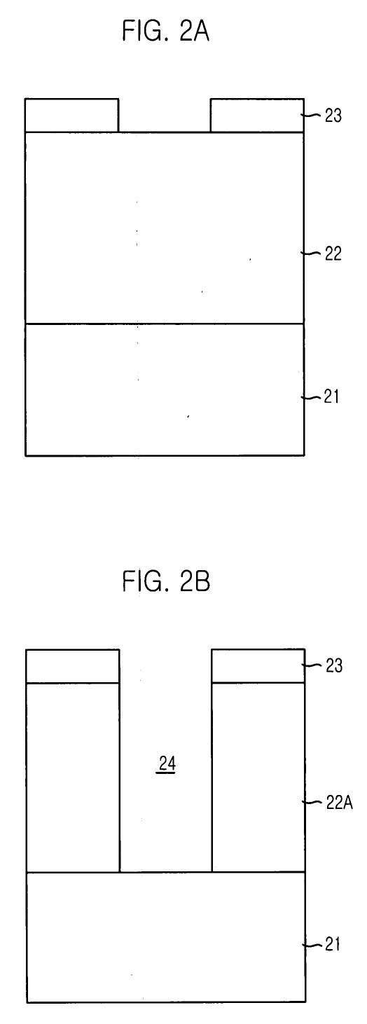

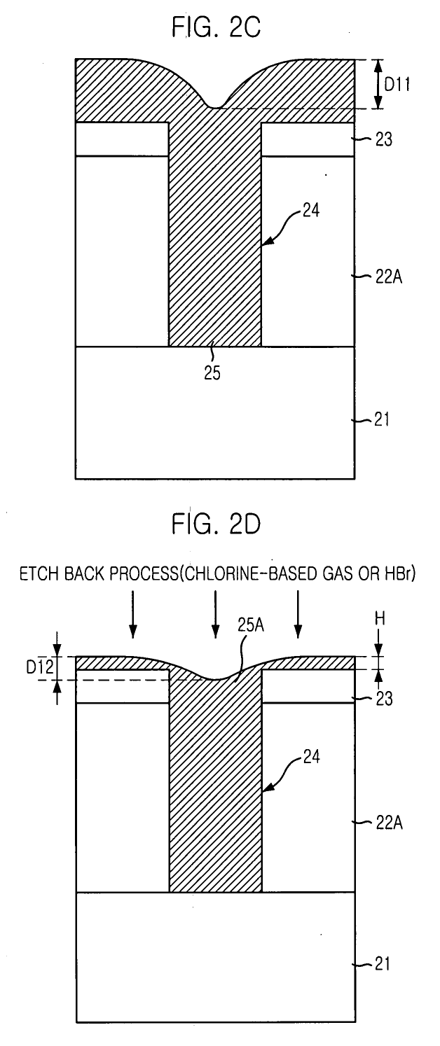

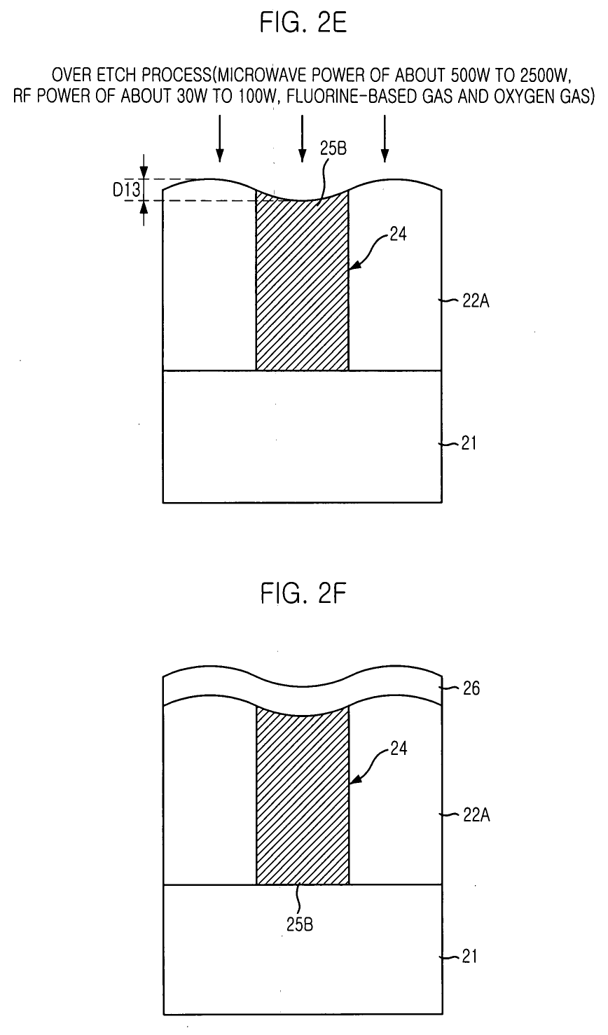

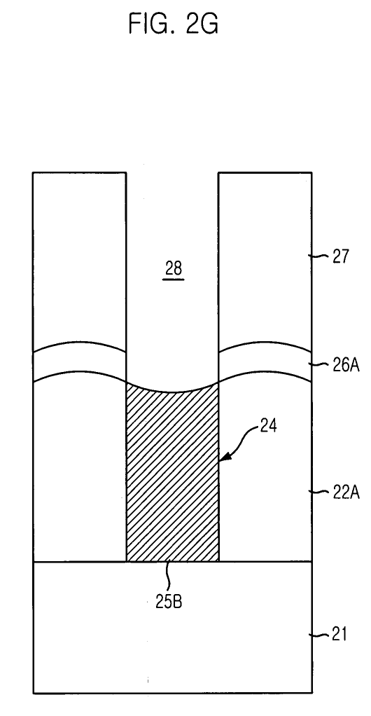

FIGS. 2A to 2G illustrate a method for fabricating a semiconductor device in accordance with an embodiment of the present invention. As shown in FIG. 2A, an inter-layer insulation layer 22 is formed over an upper portion of a substrate 21 in which a certain process is completed.

A hard mask pattern 23 is formed over the inter-layer insulation layer 22 using a mask pattern. The mask pattern used to form the hard mask pattern 23 may include a photoresist pattern. The hard mask pattern 23 is mainly used to secure a margin of a contact etch. The hard mask pattern 23 may include an oxide layer or/and a nitride layer.

As shown in FIG. 2B, the inter-layer insulation layer 22 is etched using the hard mask pattern 23 as an etch mask to form a storage node contact hole 24. A patterned inter-layer insulation layer 22A is obtained. As shown in FIG. 2C, a conductive material 25 is formed to a thickness enough to fill the storage node contact hole 24. The conductive material 25 may include polysilicon.

When the formation of the conductive material 25 is completed, a height difference D11 is generated in a surface of the conductive material 25. A thickness of the conductive material 25 over the hard mask pattern 23 and that of the conductive material 25 that fills the storage node contact hole 24 are different from each other due to a height difference of the bottom portion of the storage node contact hole 24 and the hard mask pattern 23A.

As shown in FIG. 2D, the conductive material 25 is etched performing an etch-back process. A patterned conductive material is identified by reference numeral 25A. The etch-back process is continuously performed using one of a chlorine-based gas and a hydrogen bromide (HBr) gas, and stopped above the surface of the hard mask pattern 23. Particularly, the etch-back process is performed until the conductive material 25 remains to a certain thickness H above the surface of the hard mask pattern 23. A height difference D12 in the patterned conductive material 25A is much less than the height difference D11 in the conductive material 25 shown in FIG. 2C.

As shown in FIG. 2E, an over etch process is performed to the patterned conductive material 25A mainly using a microwave power to form a storage node contact plug 25B. The microwave power and a radio frequency (RF) power lower than the microwave power are applied during the over etch process. Accordingly, an abrupt increase in etch rate can be reduced, as etch ions concentrate on the patterned conductive material 25A inside the storage node contact hole 24, according to a transformer coupled plasma (TCP) or inductively coupled plasma (ICP) type plasma etch process using a typical RF power. Particularly, in case of using the microwave power, an inflow of the etch ions to the patterned conductive material 25A inside the storage node contact hole 24 can be controlled, thereby preventing the etch rate from being abruptly increased.

As a result, when the over etch process is completed, a height difference D13 in the storage node contact plug 25B is much less than the height difference D12 in the patterned conductive material 25A as shown in FIG. 2D. Particularly, the over etch process is performed such that the height difference between the further patterned inter-layer insulation layer 22A and the storage node contact plug 25B does not exceed a thickness of about 500 Å.

A recipe of the over etch process performed to reduce the height difference in the storage node contact plug 25B will be examined in more detail. The over etch process may include using the microwave power as a main power. The RF power lower than the microwave power is also applied for the over etch process. The microwave power ranges from about 500 W to about 2,500 W, and the RF power ranges from about 30 W to about 100 W. The microwave power is about 10 times higher than the RF power.

The over etch process may include mainly using a fluorine-based gas including trifluoromethane (CHF₃) and sulfur hexafluoride (SF₆) as a main gas. A small amount of an oxygen gas is added to control an etch rate of polysilicon used to form the conductive material 25. A flow rate of the oxygen gas corresponds to about 3% to about 10% of that of the main gas. A total flow rate of a mixture gas including the main gas and the adding gas ranges from about 50 sccm to about 200 sccm.

If the over etch process is performed mainly using the microwave power, the inflow of the etch ions can be controlled inside the storage node contact hole 24 having a relatively low height difference. Thus, the etch rate can be prevented from being abruptly increased. Particularly, while dishing typically has a thickness ranging from about 600 Å to about 700 Å, dishing generated according to this embodiment of the present invention does not exceed a thickness of at least about 500 Å. When the storage node contact plug 25B is formed, the hard mask pattern 23 is etched and does not remain.

As shown in FIG. 2F, an etch barrier layer 26 is formed over an entire surface of the resultant structure including the storage node contact plug 25B with a surface having a much more reduced height difference. The etch barrier layer 26 may include a nitride layer as a material having an etch selectivity with respect to the further patterned inter-layer insulation layer 22A and a subsequent sacrificial layer. As explained above, the etch barrier layer 26 can be formed to a uniform thickness since the substrate 21 with a much more improved planarization is secured.

As shown in FIG. 2G, a sacrificial layer 27 is formed over the etch barrier layer 26, and patterned together with the etch barrier layer 26 to form a storage node hole 28 exposing the storage node contact plug 25B. A patterned etch barrier layer is identified by reference numeral 26A. The sacrificial layer 27 may include an oxide layer. Since the etch barrier layer 26 is formed to the uniform thickness, a punch-through phenomenon and a not-open phenomenon can be prevented while forming the storage node hole 28.

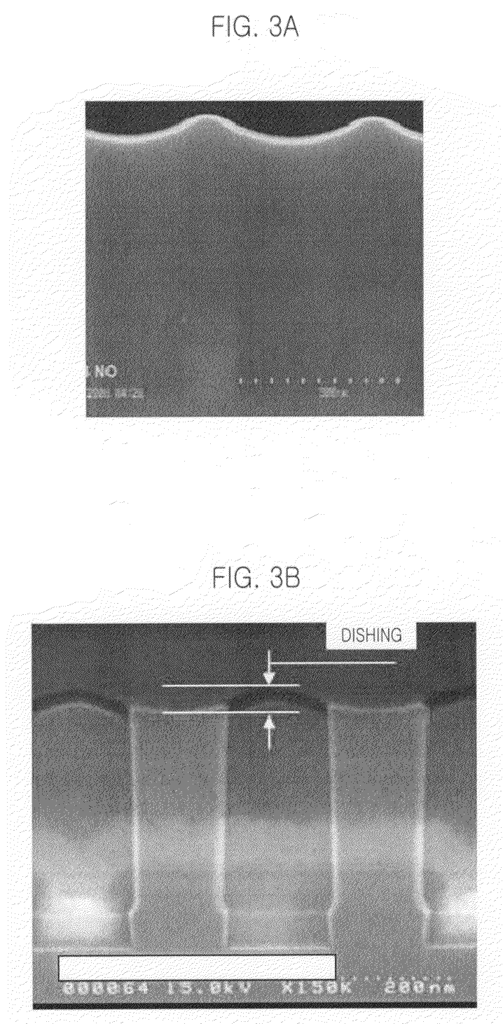

FIGS. 3A and 3B illustrate transmission electron microscopy (TEM) respectively obtained after performing a main etching process and an over etch process to form a storage node contact plug in accordance with another embodiment of the present invention. As shown in FIG. 3A, an etch-back process is performed to a conductive material and stopped right before a hard mask pattern is exposed. As a result, a reduced global height difference can be obtained. As shown in FIG. 3B, an over etch process is performed to the above resultant structure obtained by the performing of the etch-back process shown in FIG. 3A. As a result, dishing is much more reduced.

As described above, the improvement in the global height difference makes it possible to form a subsequent etch barrier layer to a uniform thickness. Accordingly, during forming a subsequent storage node, a process margin with respect to the etch barrier layer can be increased, thereby reducing a punch phenomenon and a not-open phenomenon incurred on an inter-layer insulation layer.

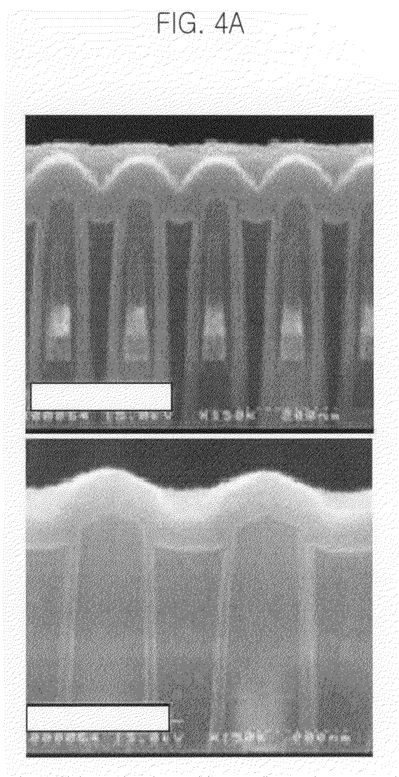

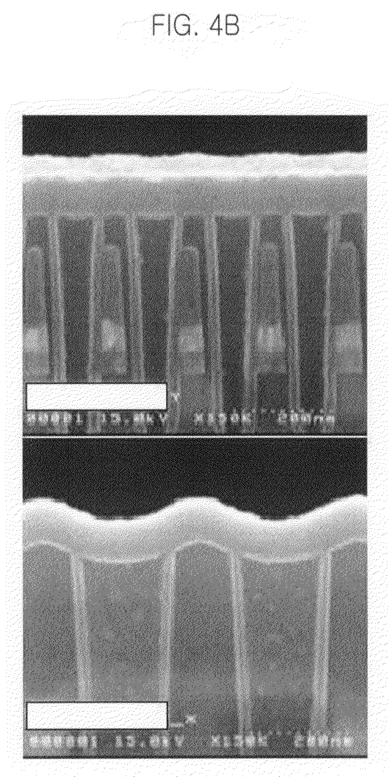

FIGS. 4A and 4B are TEM comparing a typical storage node contact plug to a storage node contact plug in accordance with another embodiment of the present invention. As shown in FIG. 4A, a serious height difference exists between the typical storage node contact plug and an inter-layer insulation layer including a bit line pattern. Accordingly, a height difference between layers subsequently formed thereon also becomes serious.

As shown in FIG. 4B, a height difference hardly exists between the storage node contact plug according to the embodiment of the present invention and an inter-layer insulation layer including a bit line pattern. Thus, subsequent layers can be formed with uniform surface shapes.

According to this embodiment of the present invention, the etch-back process is performed to the conductive material and stopped right before the hard mask pattern is exposed to form a storage node contact plug. Then, the over etch process using the microwave power as a main power is performed. As a result, the global height difference can be reduced, thereby securing uniformity of the etch barrier layer subsequently formed. Since the etch barrier layer can be formed to the uniform thickness, a punch-through phenomenon and a not-open phenomenon which may be caused when the etch barrier layer is not formed to the uniform thickness can be reduced on the inter-layer insulation layer during forming a subsequent storage node hole.

The hard mask pattern may not be used according to this embodiment of the present invention. Although the storage node contact plug and the storage node contacting the storage node contact plug are exemplified in this embodiment of the present invention, this embodiment of the present invention may be applied to other contact processes while fabricating similar semiconductor devices to improve a global height difference in addition to the storage node contact process.

According to this embodiment of the present invention, the global height difference between the inter-layer insulation layer and the contact plug can be reduced, thereby improving a degree of planarization. Accordingly, a subsequent process margin can be secured, and a punch-through phenomenon and a not-open phenomenon can be prevented. As a result, a device property and reliability can be secured.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, the method comprising:
etching an insulation layer over a substrate to form a contact hole in a patterned insulation layer;
forming a conductive layer over the resultant structure obtained after forming the contact hole;
etching the conductive layer right before the patterned insulation layer is exposed; and
etching the conductive layer such that the patterned insulation layer is exposed to thereby form a contact plug filling the contact hole.

2. The method of claim 1, wherein etching the conductive layer right before the patterned insulation layer is exposed and etching the conductive layer such that the patterned insulation layer is exposed comprise performing an etch-back process.

3. The method of claim 1, wherein etching the conductive layer such that the patterned insulation layer is exposed comprises using a microwave power.

4. The method of claim 3, wherein etching the conductive layer such that the patterned insulation layer is exposed comprises using a radio frequency (RF) power with the microwave power.

5. The method of claim 4, wherein the RF power is lower than the microwave power.

6. The method of claim 4, wherein the microwave power and the RF power have a power level difference by at least 10-fold.

7. The method of claim 4, wherein the microwave power ranges from about 500 W to 2,500 W and the RF power ranges from about 30 W to 100 W.

8. A method for fabricating a semiconductor device, the method comprising:
etching an insulation layer over a substrate to form a contact hole in a patterned insulation layer;
forming a polysilicon layer over the resultant structure obtained after forming the contact hole;
etching the polysilicon layer right before the patterned insulation layer is exposed; and
etching the polysilicon layer such that the patterned insulation layer is exposed to thereby form a contact plug filling the contact hole.

9. The method of claim 8, wherein etching the polysilicon layer right before the patterned insulation layer is exposed and etching the polysilicon layer such that the patterned insulation layer is exposed comprise performing an etch-back process.

10. The method of claim 8, wherein etching the polysilicon layer such that the patterned insulation layer is exposed comprises using a microwave power.

11. The method of claim 10, wherein etching the polysilicon layer such that the patterned insulation layer is exposed comprises using a radio frequency (RF) power with the microwave power.

12. The method of claim 11, wherein the RF power is lower than the microwave power.

13. The method of claim 11, wherein the microwave power and the RF power have a power level difference by at least 10-fold.

14. The method of claim 11, wherein the microwave power ranges from about 500 W to 2,500 and the RF power ranges from about 30 W to 100.

15. The method of claim 8, wherein etching the polysilicon layer such that the patterned insulation layer is exposed comprises using a fluorine-based gas as a main gas with adding an oxygen gas to the main gas, wherein the fluorine-based gas includes one of CHF₃ and SF₆.

16. The method of claim 15, wherein a flow rate of the oxygen gas corresponds to about 3% to 10% of the flow rate of the main gas, and a total flow rate of a mixture gas including the main gas and the oxygen gas ranges from about 50 sccm to 200 sccm.

17. The method of claim 8, wherein etching the polysilicon layer right before the patterned insulation layer is exposed comprises using one of a chlorine-based gas and a HBr gas.

18. The method of claim 8, further comprising:
forming an etch barrier layer over the contact plug and the patterned insulation layer;
forming a sacrificial layer over the etch barrier layer; and
etching the sacrificial layer to form a storage node hole.

19. The method of claim 8, wherein etching the insulation layer to form the contact hole comprises using a hard mask pattern, wherein the first etching of the polysilicon layer proceeds right before the hard mask pattern is exposed and the second etching of the polysilicon layer proceeds to remove the hard mask pattern.

20. The method of claim 19, wherein the hard mask pattern comprises one of an oxide-based material, a nitride-based material, and a combination thereof.
